(19) United States
(12) Patent Application Publication
(10) Pub. No.: US 2007/0158031 A1
(43) Pub. Date: Jul. 12, 2007

(54) Substrate adsorption device and substrate bonding device

(75) Inventor: Hidetomo Miyake, Mie (JP)

Correspondence Address: EDWARDS ANGELL PALMER & DODGE LLP, P.O. BOX 55874, BOSTON, MA, 02205, US

(73) Assignee: Sharp KAbushiki Kaisha, Osaka (JP)

(21) Appl. No.: 10/583,639

(22) PCT Filed: Jan. 13, 2005
(86) PCT No.: PCT/JP05/00712

§ 371 Date: Jun. 20, 2006

(30) Foreign Application Priority Data
Jan. 16, 2004 (JP) 2004-009021

(51) Int. Cl. B32B 37/00; H01L 21/68; B25B 11/00

(52) U.S. Cl. 156/581; 156/538; 269/21

(57) ABSTRACT

A substrate adsorption device 1 includes: a stage 11 having an adsorption face 12 for holding a substrate 20; a plurality of adsorption ports 13 formed in a region of the adsorption face 12 of the stage 11; and a vacuum pump 14 connected to each adsorption port through an air discharge path 17. A pressure sensor 18 for detecting the pressure in the air discharge path 17 is provided, and a plurality of leak trenches 30 open to both the adsorption face 12 of the stage 11 and a side face of the stage 11 are formed in a region of the stage 11 except the region where the adsorption ports 13 are formed. With such a low-cost and simple structure, a foreign matter 15, which is a factor of inviting damage to the substrate 20, is detected, to prevent damage to the substrate 20.

### CROSS REFERENCE TO RELATED APPLICATIONS

The disclosure of Japanese Patent Application No. 2004-009021 filed Jan. 16, 2004, including specification, drawings and claims is incorporated herein by reference in its entirety.

### TECHNICAL FIELD

The present invention relates to a substrate adsorption device and a substrate bonding device including a stage for holding by adsorbing a substrate, and particularly relates to countermeasures for preventing malfunction caused due to the existence of a foreign matter between the stage and the substrate.

### BACKGROUND ART

Conventionally, substrate adsorption devices for holding by adsorbing a substrate as an object to be processed to a flat stage have been known (see Patent Document 1 and Patent Document 2, for example.).

FIG. 12 is a perspective view schematically illustrating the main portion of a substrate adsorption device 100, and FIG. 13 is a side view schematically illustrating a substrate bonding device 120 composed of a pair of the substrate adsorption devices 100 facing each other.

As shown in FIG. 12 and FIG. 13, each substrate adsorption device 100 includes a stage 101 for holding by adsorbing a substrate 110 at an adsorption face 102. A plurality of adsorption ports 103 opening in the adsorption face 102 are formed in the stage 101. The adsorption ports 103 are formed at, for example, four corners of the stage 101, respectively. Further, the adsorption ports 103 are connected to a vacuum pump 104 through an air discharge path 107. With this construction, the substrate 110 is adsorbed and held by driving a vacuum pump 104 while the substrate 110 is placed on the adsorption face 102 of the stage 101.

When the substrate 110 as an object to be processed is not fixed securely and moves on the stage, the substrate 110 cannot be processed accurately. For this reason, the substrate adsorption device 100 is demanded to be capable of holding and adsorbing the substrate 110 securely.

In order to satisfy the above demand, a pressure gage 118 is provided in the air discharge path 107 that connects the adsorption ports 103 and the vacuum pump 104 in Patent Document 1. When the pressure within the air discharge path 107 detected by the pressure gage 118 is larger than a predetermined value, the state that the substrate 110 is not adsorbed securely is detect.

On the other hand, in Patent Document 2, though not shown, a plurality of adsorption trenches are formed in the surface portion of the stage and adsorption ports are formed in the bottom of the adsorption trenches. Vacuum force is generated sequentially, differentially in time in the adsorption trenches, to restrict bow of the substrate accompanied by adsorption and to prevent leakage of the vacuum force.

The substrate adsorption device 100 is used for, for example, a substrate bonding device 120 for manufacturing a liquid crystal display panel by bonding a pair of substrates. In general, the liquid crystal display panel is composed of a TFT substrate in which a plurality of switching elements such as TFTs are provided, a counter substrate in which a color filter and the like are provided, and a liquid crystal layer interposed between the TFT substrate and the counter substrate.

Each of the TFT substrate and the counter substrate includes, as shown in FIG. 13, a glass substrate 110 and an alignment film 111 uniformly provided on the glass substrate 110. The alignment film 111 is provided for defining the initial orientation of the liquid crystal molecules of the liquid crystal layer.

The stages 101 of the substrate adsorption devices 100 are moved to be closed to and press against each other while adsorbing the glass substrates 110, respectively, to bond the TFT substrate and the counter substrate to each other. Wherein, a large number of, for example, spacers 112 are sprayed on the surface of the assignment film 111 of the TFT substrate. Each spacer 112 is formed of a ball-shaped particle for keeping a predetermined space between the TFT substrate and the counter substrate.

If a foreign matter 105 such as dust, a metal particle and the like exists between the adsorption face 102 of the stage 101 and the glass substrate 110, the glass substrate 110 is deformed in a convex shape locally by the foreign matter 105, as shown in a side section of FIG. 14. As a result, the foreign matter 105 may scratch the glass substrate 110, so that the glass substrate 110 becomes defective. Further, the foreign matter 105 causes pressure concentration at a part where the foreign matter 105 exists, as shown in a side view of FIG. 15, to scratch the alignment film 111 or the glass substrate 110 in bonding the TFT substrate and the counter substrate.

In this connection, there is a known technique that a region of the stage corresponding to the central region of the glass substrate (e.g., a display region) is recessed (see, for example, Patent Document 3). In detail, as shown in a side section of FIG. 16, the recessed portion 101a is formed in the middle of the stage 101. The adsorption face 101 is formed around the recessed potion 101a and a plurality of adsorption ports 103 are formed in the adsorption face 102. With this construction, the glass substrate 110 can be kept away from the foreign matter 105 with a predetermined space left between the bottom of the recessed portion 101a and the glass substrate 110 even if the foreign matter 105 enters within the recessed portion 101a.

(Patent Document 1) Japanese Patent Application Laid Open Publication No. 11-288957A

(Patent Document 2) Japanese Patent Application Laid Open Publication No. 9-80404A

(Patent Document 3) Japanese Patent Application Laid Open Publication No. 10-268325A

### DISCLOSURE OF THE INVENTION

However, in the substrate adsorption device of Patent Document 3, for adsorbing and holding a various kinds of substrates difference in size securely, it is necessary to change the size of the recessed portion according to the sizes of the substrates. In this connection, the stage must be exchanged for respective different-sized substrates, which increases device cost and involves labor for exchanging the stages.

Recently, size and variation of the liquid crystal panels are increasing, and therefore, the above problem is significant in substrate adsorption devices for holding such liquid crystal panels.

In addition, in Patent Document 3, a foreign matter larger than the depth of the recessed portion may be in contact with the substrate, with a result of no effect exhibited.

The present invention has been made in view of the above problems and has its object of preventing a flaw on a substrate by detecting existence of a foreign matter, which is a factor of a flaw on the substrate, with a low-cost and simple construction of a substrate adsorption device for holding by adsorbing the substrate and a substrate bonding device provided therewith.

To attain the above object, a plurality of leak trenches open to both an adsorption face of a stage and a side face of the stage are formed in the present invention.

Specifically, a substrate adsorbing device according to the present invention includes: a stage including an adsorption face for holding a substrate; a plurality of adsorption ports formed in a region of the adsorption face of the stage; an air discharge path connected to each of the adsorption ports; pressure reducing means connected to the adsorption ports through the discharging path; and pressure detecting means that detects pressure in the air discharge path, wherein a plurality of leak trenches open to both the adsorption face of the stage and a side face of the stage are formed in a region of the stage except a region where the adsorption ports are formed.

The pressure detecting means may be provided in the air discharge path for each of the adsorption ports.

For each of the adsorption ports, the pressure detecting means and an opening/closing mechanism for opening/closing the corresponding adsorption port based on a pressure state detected by the corresponding pressure detecting means may be provided in the air discharge path.

It is preferable that the opening/closing mechanism closes the corresponding adsorption port when the pressure detecting means does not detect a vacuum state.

It is preferable to form the leak trenches in a grid pattern in the region of the adsorption face of the stage.

It is preferable to form the adsorption ports at centers of regions surrounded by the leak trenches formed in the grid pattern, respectively.

The leak trenches may be formed in a stripped pattern in the region of the adsorption face of the stage.

A substrate bonding device according to the present invention includes two substrate adsorption devices as above, the substrate adsorption devices are arranged so that the adsorption faces of the stages face each other, and the stages are allowed to be close to each other while adsorbing and holding substrate, respectively, to bond the substrates to each other.

### Operation

Operation of the present invention will be described next.

For adsorbing and holding the substrate by the substrate adsorption device, the substrate is placed on the adsorption face of the stage first. Then, the pressure reducing means is driven to discharge the air between the substrate and the adsorption face from the adsorption ports through the air discharge path. In other words, vacuum force is generated between the substrate and the adsorption face. Whereby, the substrate adsorption device holds by adsorbing the substrate at a predetermined position on the stage.

If a foreign matter enters between the substrate and the adsorption face, the substrate adsorbed to the adsorption face is deformed in a convex shape locally by the foreign matter. Namely, a certain space is created around the foreign matter between the substrate and the adsorption face. The space communicates with the adsorption ports and the leak trenches so that the air in the space is discharged through the adsorption ports while air is introduced to the space from the leak trenches. As a result, the pressure in the air discharge path detected by the pressure detecting means becomes larger when a foreign matter exists than the case with no foreign matter exists. In other words, whether a foreign matter exists between the substrate and the adsorption face or not can be judged according to the pressure detected by the pressure detecting means.

It should be noted that the substrate hermetically plugs the adsorption ports by elastic deformation even with a foreign matter exists in the conventional substrate adsorption devices, as shown in FIG. 14. In this connection, even with the above pressure detecting means provided, a foreign matter cannot be detected through the pressure detecting means because the pressure detected through the pressure detecting means is constant regardless of the presence or absence of a foreign matter between the substrate and the adsorption face.

Further, provision of the pressure detecting means at each adsorption port of the air discharge path enables to detect the pressure of air discharged from each adsorption port, and accordingly, the position of a foreign matter, if exists between the substrate and the adsorption face, can be specified.

Moreover, the opening/closing mechanism is provided at each adsorption port of the air discharge path in combination with the pressure detecting means, which enables opening/closing of each adsorption port based on the detected pressure. Especially, when the opening/closing mechanism closes an adsorption port of which vacuum state is not detected by the pressure detecting means, leakage through the adsorption port stops. As a result, the substrate can be held securely at the other adsorption ports of which vacuum states are detected.

In addition, the formation of the leak trenches in a grid pattern or in a stripped pattern enables uniform detection of a foreign matter on the adsorption face.

For bonding substrates by the substrate bonding device, the substrates are placed on the stages, respectively, and the substrates are adsorbed and held to the adsorption faces of the stages of the substrate adsorption devices, respectively, by driving the pressure reducing means. Then, the stages are allowed to be closed to and pressed against each other with the substrates being held and adsorbed. Whereby, the substrates are bonded to each other with no foreign matter left between the substrates and the adsorption faces.

In the substrate adsorption device according to the present invention, a foreign matter, which is a factor of damaging the substrate, left between the substrates and the adsorption faces can be detected according to the pressure detected by the pressure detecting means, and thus, a flaw on the substrate is prevented

### BRIEF DESCRIPTION OF THE DRAWINGS

FIG. 1 is a perspective view schematically illustrating the main portion of a substrate adsorption device in the first embodiment.

FIG. 2 is a section showing a side section of the substrate adsorption device in the first embodiment.

FIG. 3 is a side view schematically illustrating a substrate bonding device including the substrate adsorption devices in the first embodiment.

FIG. 4 is a perspective view schematically illustrating the main portion of a substrate adsorption device in the second embodiment.

FIG. 5 is a section showing a side section of a substrate adsorption device in the third embodiment.

FIG. 6 is a section showing a side section of a substrate adsorption device in the fourth embodiment.

FIG. 7 is a perspective view schematically illustrating a sealing material dispenser in the fifth embodiment.

FIG. 8 is an explanatory drawing showing an exposure apparatus and optical paths in the sixth embodiment.

FIG. 9 is a side view illustrating a chopper in the seventh embodiment.

FIG. 10 is a perspective view schematically illustrating a web cleaner in the eighth embodiment.

FIG. 11 is an explanatory drawing schematically illustrating a coating apparatus in the ninth embodiment.

FIG. 12 is a perspective view schematically illustrating the main portion of a conventional substrate adsorption device.

FIG. 13 is a side view illustrating a substrate bonding device including conventional substrate adsorption devices.

FIG. 14 is a side section showing the state where a foreign matter enters in the conventional substrate adsorption device.

FIG. 15 is a side view showing the state where a foreign matter enters in the conventional substrate bonding device.

FIG. 16 is a side section illustrating a conventional substrate adsorption device including a stage in which a recessed portion is formed.

### BEST MODE FOR CARRYING OUT THE INVENTION

The embodiments of the present invention will be described below with reference to accompanying drawings. Wherein, the present invention is not limited to the following embodiments.

### FIRST EMBODIMENT

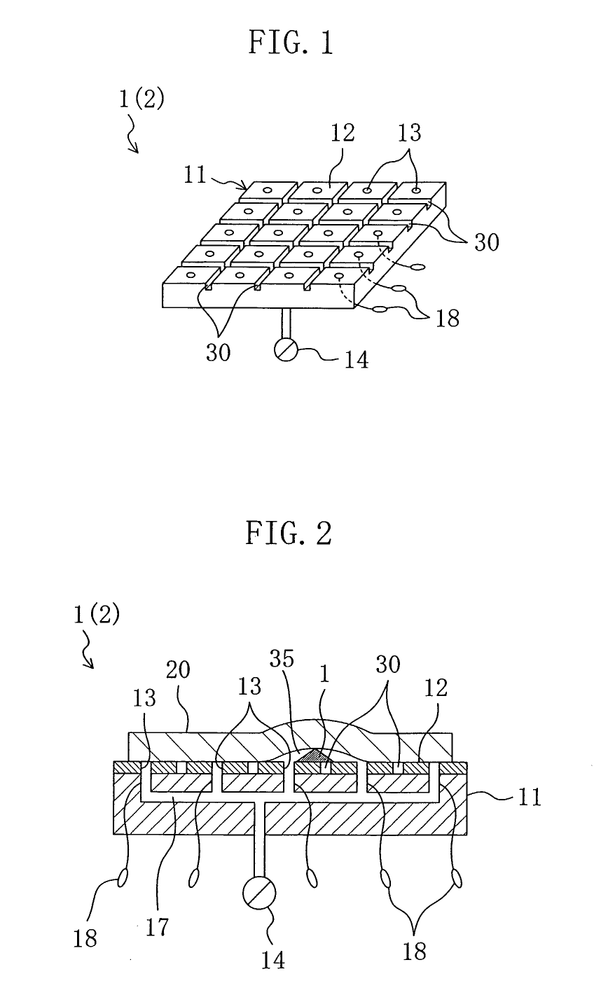

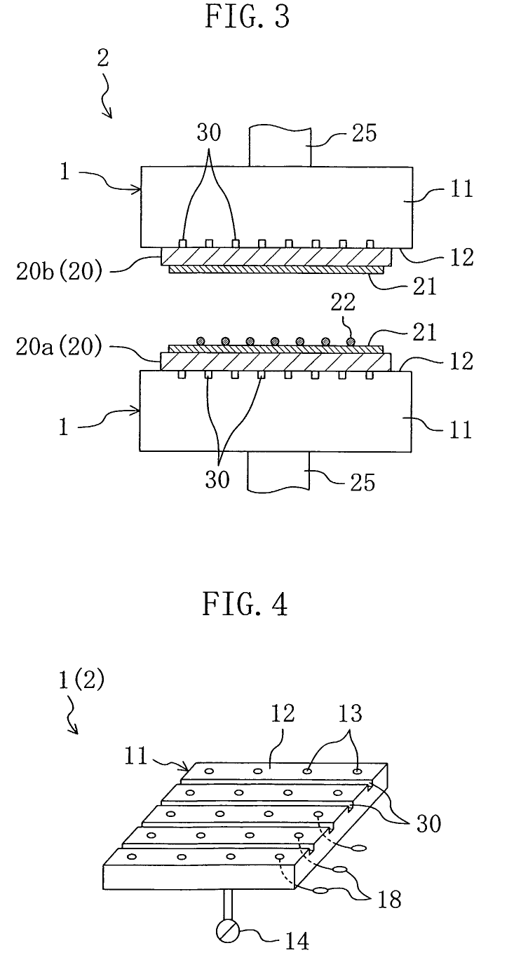

FIG. 1 through FIG. 3 show an embodiment of a substrate adsorption device 1 and a substrate bonding device 2 according to the present invention. FIG. 1 is a perspective view schematically illustrating the substrate adsorption device 1, FIG. 2 is a section schematically illustrating the substrate adsorption device 1, and FIG. 3 is a side view of the substrate bonding device 2.

The substrate bonding device 2 is a device used for manufacturing, for example, a liquid crystal display panel by bonding a pair of substrates 20, and is composed of the two substrate adsorption devices 1, as shown in FIG. 3.

The liquid crystal display panel is composed of a TFT substrate 20a in which a plurality of switching elements such as TFTs are provided, a counter substrate 20b in which a color filter and the like are provided, and a liquid crystal layer (not shown) interposed between the TFT substrate 20a and the counter substrate 20b, as shown in FIG. 3. An alignment film 21 is uniformly formed on each surface of the TFT substrate 20a and the counter substrate 20b. The alignment film 21 defines the initial orientation of liquid crystal molecules in the liquid crystal layer. A large number of spacers 22 are splayed on the alignment film 21 of the TFT substrate 20a or the counter substrate 20b. The spacers 22 are ball-shaped particles for keeping a predetermined space between the TFT substrate 20a and the counter substrate 20b.

Each of the TFT substrate 20a and the counter substrate 20b, which are glass substrates, has a thickness in the range between 0.6 mm and 1.1 mm, both inclusive, and a size of, for example, 680 mm wide and 880 mm long.

The substrate adsorption device 1 includes: a stage 11 having an adsorption face 12 for holding the substrate 20, which is the TFT substrate 20a or the counter substrate 20b; a plurality of adsorption ports 13 formed in a region of the adsorption face 12 of the stage 11; and a vacuum pump 14 serving as pressure reducing means which is connected to each adsorption port 13 through an air discharge path 17, as shown in FIG. 1 and FIG. 2. The substrate 20 is adsorbed and held to the adsorption face 12 of the stage 11 by driving the vacuum pump 14.

The stage 11 is formed of a plate member made of, for example, aluminum or the like and having a predetermined thickness. It is preferable that the adsorption face 12 of the stage 11 is subjected to anodic oxidation. The stage 11 is formed to have a size of, for example, 1000 mm wide and 1000 mm long. As shown in FIG. 3, a part of which is omitted, an elevating machine 25, such as an air cylinder, for moving up and down the stage 11 is provided in back of each stage 11 (i.e., the side opposite the adsorption face 12).

The adsorption face 12 is a flat face for holding by adsorbing the substrate 20 in a flat plate state. The adsorption ports 13 are formed open to the adsorption face 12 and arranged in matrix in the adsorption face 12, as shown in FIG. 1.

The air discharge path 17 is formed inside and outside the stage 11, as shown in FIG. 2, and connects the adsorption ports 12 to the vacuum pump 14. In detail, the air discharge path 17 extends from each adsorption port 13 to the inside of the stage 11 and is gathered into a single path of the air discharge path 17, and the end thereof is connected to a suction port (not shown) of the vacuum pump 14.

In the air discharge path 17, pressure sensors 18 are provided which serve as pressure detecting means for detecting the pressure inside the air discharge path 17. The pressure sensors 18 are provided at the adsorption ports 13, respectively, as shown in FIG. 2. With the pressure sensors 18, each pressure of the air discharged from the adsorption ports 13 is detected separately.

A plurality of leak trenches 30 are formed in a grid pattern in the adsorption face 12 of the stage 11. The leak trenches 30 are formed, as shown in FIG. 2, in a region except the region where the adsorption ports 13 are formed, and are open outside to both the adsorption face 12 of the stage 11 and the side faces of the stage 11. In other words, the inside of the leak trenches 30 communicates with outside of the stage 11 so as to be open to air when the substrate 20 is placed on the adsorption face 12. The leak trenches 30 have a trench depth and width of 2 mm, and are formed at regular intervals of 100 mm.

Each adsorption port 13 is formed to have a diameter of, for example, 20 mm, and is arranged at the center of the region surrounded by the plurality of leak trenches 30 formed in a grid pattern. Namely, the adsorption ports 13 are arranged, for example, in the 100 mm pitch, similar to the leak trenches 30.

The substrate bonding device 2 is composed of paired substrate adsorption devices 1 arranged so that the adsorption faces 12 of the stages 11 face each other, as shown in FIG. 3. The stages 11 are allowed to be close to each other while the substrates are adsorbed and held, thereby bonding the substrates.

### Operation of Device

Each operation of the substrate adsorption device 1 and the substrate bonding device 2 will be described next.

For adsorbing and holding the substrate 20 by the substrate adsorption device 1, the substrate 20 is placed on the adsorption face 12 of the stage 11 first. Then, the vacuum pump 14 is driven to discharge air between the substrate 20 and the adsorption face 12 from each adsorption port 13 through the air discharge path 17, so that vacuum force is generated between the substrate 20 and the adsorption face 12. Whereby, the substrate adsorption device 1 holds by adsorbing the substrate 20 at a predetermined position on the stage 11. At this time, the pressure sensor 18 detects the pressure inside the air discharge path 17 that might become vacuum, to confirm that the pressure is not exceeding a predetermined value.

While, a particle of metal, glass, or the like, which is a foreign matter 15, may be adhered to the substrate 20 in the previous process, to enter between the substrate 20 and the adsorption face 12. If the foreign matter 15 is left between the substrate 20 and the adsorption face 20, the substrate 20 adsorbed to the adsorption face 12 is deformed into a convex shape locally by the foreign matter 15, as shown in FIG. 2.

In the conventional substrate bonding device 120 with no leak trenches formed, pressure concentration is caused between the substrates 20 in bonding of the substrates 20, and the alignment film 21 is scratched when the size of the foreign matter 15 is larger than 15 mm. Further, the substrates 20 themselves may be scratched by the foreign matter 15.

In contrast, each interval of the leak trenches 30 and the adsorption ports 13 is formed at regular intervals of 100 mm in the case where the glass substrates 20 having a predetermined elasticity has a thickness in the range between 0.6 mm and 1.1 mm, both inclusive. Therefore, the space 35 between the substrate 20 and the adsorption face 12, which is created around the foreign matter 15 of 0.5 mm or larger in size, can communicate with both an adsorption port and the leak trenches 30.

As a result, air is introduced from the leak trenches 30 while the air in the space 35 is discharged from the adsorption ports 13, so that the pressure in the air discharge path 17 detected by the pressure sensor 18 becomes larger when the foreign matter 15 exists than when the foreign matter 15 does not exist. Thus, the foreign matter 15 is detected according to the value of the pressure sensor 18.

Upon detection of the foreign matter 15, the substrates 20 are cleaned to remove the foreign matter 15 before bonding the substrates 20 actually.

Thereafter, the TFT substrate 20a and the counter substrate 20b, which are substrates 20, are adsorbed and held to the stages 11 of the paired substrate adsorption devices 1, respectively, with no foreign matter 15 left, and the stages 11 are allowed to be closed to each other by the elevating machine 25. Subsequently, the pressure is applied to the TFT substrate 20a and the counter substrate 20b to bond them to each other. Then, a liquid crystal material is injected into a space (cell gap) between the TFT substrate 20a and the counter substrate 20b, thereby completing a liquid crystal display panel.

### EFFECTS IN FIRST EMBODIMENT

The size of the space 35 created around the foreign matter 15 between the substrate 20 and the adsorption face 12 depends on the relationship between the thickness of the substrate 20 and the size of the foreign matter 15 existing between the substrate 20 and the adsorption face 12, which is a factor of a flaw on the alignment film 21 and the substrate 20 itself. According to the present embodiment, interval setting of the leak trenches 30 and the like, taking the foregoing relationship in consideration, enables communication of the space 35 with both the adsorption ports 13 and the leak trenches 30.

Hence, the pressure in the air discharge path 17 can be made larger when the foreign matter 15 exists between the substrate 20 and the adsorption face 12 than when the foreign matter 15 does not exists therebetween by introducing air to the space 35 from the leak trenches 30 while discharging the air in the space 35 from the adsorption ports 13. As a result, detection of the pressure in the air discharge path 17 by the pressure sensors 18 leads to judgment as to whether the foreign matter 15 exists therebetween.

Further, the uniform formation of the leak trenches 30 in the stage 11 secures substrate adsorption and holing, and detection of a foreign matter in a plurality of substrates different in size. In other words, it is unnecessary to exchange stages for respective substrates different in size, and therefore, the device cost is reduced and labor for exchanging the stages is dispensed with. A flaw on the substrate 20 and the like caused by entering of the foreign matter 15 is prevented with low cost and simple construction, regardless of the size of the substrates.

Further, the provision of the pressure sensor 18 at each adsorption port 13 enables detection of the pressure of the air discharged from each adsorption port 13. Hence, the position of the foreign matter 15 existing between the substrate 20 and the adsorption face 12 can be specified.

Moreover, the formation of the leak trenches 30 in a grid pattern enables uniform detection of the foreign matter 15 on the adsorption face 12.

In addition, the application of the substrate adsorption devices 1 to the substrate bonding device 2 enables bonding of the substrates 20 with no foreign matter 15 left between the substrates 20 and the adsorption faces 12, thereby enhancing the quality of the liquid crystal display panel as a product.

### SECOND EMBODIMENT

FIG. 4 shows the second embodiment according to the present invention. Wherein, the same reference numerals are assigned to the same members as in FIG. 1 through FIG. 3 and the detailed description thereof is omitted in the following embodiments.

FIG. 4 is a perspective view illustrating the stage 11 in the second embodiment. In the substrate adsorption devices 1 applied to the substrate bonding device 2 in the present embodiment, the leak trenches 30 are formed in a region of the adsorption face 12 in a stripped pattern, which is the feature.

In detail, the plural leak trenches 30 are formed in the stage 11 in parallel with one another at regular intervals. The plural adsorption ports 13 are arranged along the leak trenches 30 at regular intervals between the corresponding adjacent leak trenches 30. Each adsorption port 13 is formed at the center between the corresponding adjacent leak trenches 30. Thus, the formation of the leak trenches 30 in a stripped pattern can attain the same effects in the first embodiment.

### THIRD EMBODIMENT

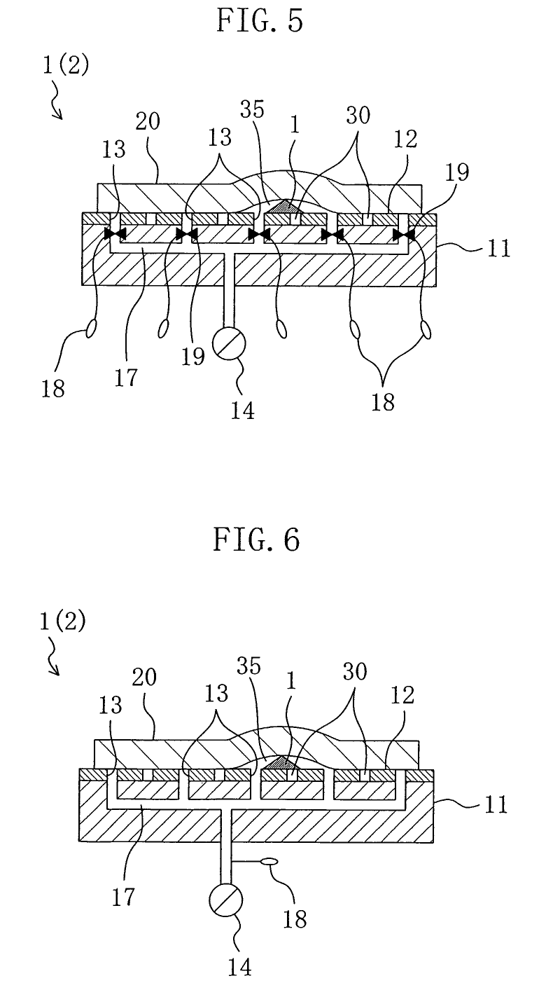

FIG. 5 shows the third embodiment according to the present invention. In the present embodiment, valves 19 serving as an opening/closing mechanism are added to the substrate adsorption devices 1 in the first embodiment.

In detail, for each adsorption port 13, the pressure sensor 18 and a valve 19 for opening/closing the adsorption port 13 based on the pressure detected by the pressure sensor 18 are provided in the air discharge path 17, as show in FIG. 5. The valve 19 closes the corresponding adsorption port 13 when the corresponding pressure sensor 18 does not detect the vacuum state.

For adsorbing and holding the substrate 20 by the substrate adsorption device 1, the substrate 20 is placed on the adsorption face 12 of the stage 11 and the air between the substrate 20 and the adsorption face 12 is discharge from each adsorption port 13 through the air discharge path 17 in the same way as in the first embodiment.

If the foreign matter 15 exists between the substrate 20 and the adsorption face 12 at that time, the substrate 20 adsorbed to the adsorption face 12 is deformed in a convex shape locally by the foreign matter 15.

In so doing, the glass substrate 20 closes the adsorption ports 13 in the region of the stage 11 where the foreign matter 15 does not exists, so that the pressure sensors 18 detects the vacuum state in the air discharge path 17 continuing to the adsorption ports 13.

On the other hand, in the region of the stage 11 where the foreign matter 15 exists, both the adsorption port 13 and the leak trench 30 communicate with the space 35 created around the foreign matter 15 between the substrate 20 and the adsorption face 12. In this connection, a comparatively large value of pressure is detected in the air discharge path 17 continuing to the adsorption port 13 communicating with the space 35, which means no detection of the vacuum state. Upon no detection of the vacuum state, the valve 19 is driven to close the adsorption port 13 communicating the space 35.

Hence, according to the present embodiment, the existence of a foreign matter can be detected according to the detected values by the pressure sensors 18 and the glass substrate 20 can be adsorbed and held securely with no air leakage from the lead trenches 30 even when the foreign matter 15 exists between the stage 11 and the glass substrate 20.

### FOURTH EMBODIMENT

FIG. 6 shows the fourth embodiment according to the present invention. While the pressure sensor 18 is provided for each of the adsorption ports 13 in the first embodiment, only one pressure sensor 18 is provided in the present embodiment.

In detail, as shown in the section of FIG. 6, the pressure sensor 18 is provided at the confluence portion of the air discharge path 17 so as to detect the pressure of the air discharged from each adsorption port 13 and introduced into the vacuum pump 14.

With this construction, the pressure at the confluence portion of the air discharge path 17 becomes large when air is introduced from a leak trench 30, with a result of detection of the foreign matter 15 from the pressure sensor 18. Further, the reduction of the number of the pressure sensors 18 leads to reduction of the device cost.

### FIFTH EMBODIMENT

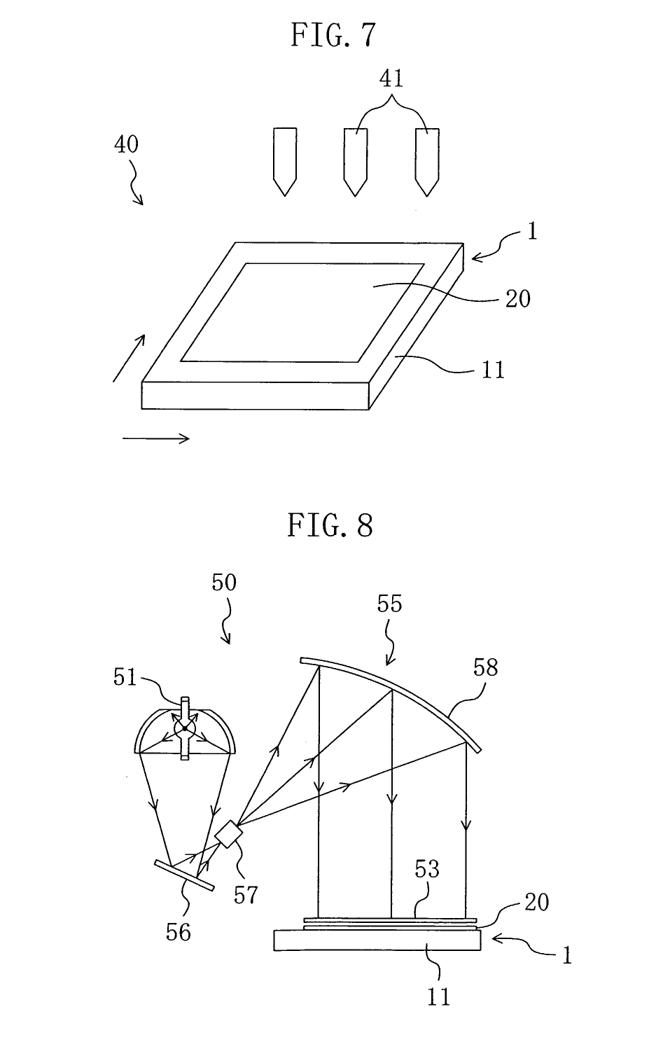

FIG. 7 shows the fifth embodiment of the substrate adsorption device 1 according to the present invention. FIG. 7 is a perspective view schematically illustrating a sealing material dispenser 40.

The sealing material dispenser 40 includes the substrate adsorption device 1 for holding by adsorbing the substrate 20, and cylinders 41 for discharging an adhesive so that the adhesive is applied at the predetermined portion on the substrate 20 through the cylinders 41. The distance between the tip ends of the cylinders 41 and the surface of the substrate 20 is kept to be several micrometers. The stage 11 of the substrate adsorption device 1 is set movable in a two-dimensional direction.

The sealing material dispenser 40 is required to have high accuracy for adhesive plotting to the substrate 20. However, existence of a foreign matter between the substrate 20 and the adsorption face of the stage 11 changes the distance between the tip ends of the cylinders 41 and the surface of the substrate 20, with a result of defect in the adhesive application.

For tackling this problem, the substrate adsorption device 1 according to the present invention is applied to the sealing material dispenser 40, whereby the substrate 20 can be adsorbed and held with no foreign matter left between the substrate 20 and the adsorption face of the stage 11, thereby preventing a defect in the adhesive application.

### SIXTH EMBODIMENT

FIG. 8 shows the sixth embodiment of the substrate adsorption device 1 according to the present invention. FIG. 8 is an explanatory drawing schematically illustrating an exposure apparatus 50.

The exposure apparatus 50 is used for forming a layered pattern in the substrate 20 by, for example, photolithography or the like. The exposure apparatus 50 in the present embodiment is an exposure apparatus of proximity printing type, and includes an extra-high pressure mercury lamp 51, an optical system 55 for setting light of the extra-high pressure mercury lamp 51 to be parallel rays, and the substrate adsorption device 1 for holding by adsorbing the substrate 20.

The optical system 55 is composed of, for example, a dichroic mirror 56 for reflecting light of the extra-high pressure mercury lamp 51, a fly-eye lens 57 for refracting the light reflected on the dichroic mirror 56, and a convex mirror 58 for setting the light transmitted through the fly-eye lens 57 to be parallel rays.

While the substrate 20 is adsorbed to the stage 11 of the substrate adsorption device 1, the light is irradiated to the substrate 20 through a mask 53, to form a predetermined resist pattern in the substrate 20.

The above exposure apparatus 50 is required to have high exposure accuracy for accurate patterning. However, existence of a foreign matter between the substrate 20 and the adsorption face of the stage 11 bows the substrate 20, resulting in uninformed exposure. Thus, highly accurate patterning is impossible.

For tackling this problem, the substrate adsorption device 1 according to the present invention is applied to the exposure apparatus 50. Hence, the substrate 20 is adsorbed and held with no foreign matter existing between the substrate 20 and the adsorption face of the stage 11, thereby preventing exposure irregularity and attaining highly accurate patterning.

It is noted that the substrate adsorption device 1 according to the present embodiment is applicable to other exposure apparatuses such as exposure apparatuses of mirror projection type, stepper type, and the like.

### SEVENTH EMBODIMENT

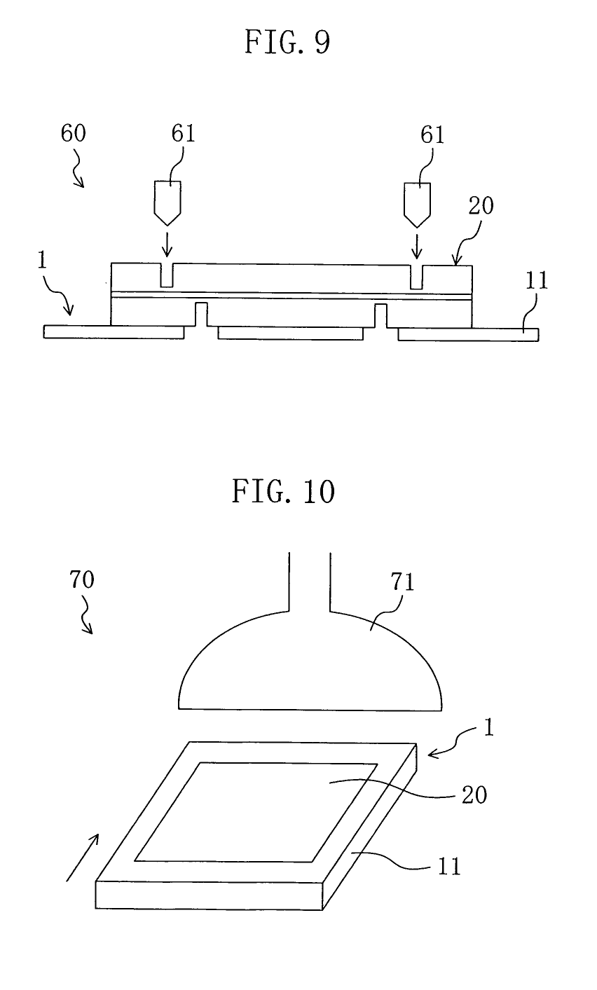

FIG. 9 shows the seventh embodiment of the substrate adsorption device 1 according to the present invention. FIG. 9 is an explanatory drawing schematically showing a chopper 60.

The chopper 60 chops the substrate 20 such as a liquid crystal display panel and the like into a predetermined size and conveys the chopped substrate 20. The chopper 60 includes the substrate adsorption device 1 for holding by adsorbing the substrate 20, and a chopping mechanism 61 for chopping the substrate 20 held by the substrate adsorption device 1.

The application of the substrate adsorption device 1 according to the present invention to the chopper 60 prevents damage to the substrate 20, which is accompanied by chopping and conveyance, because the substrate 20 can be adsorbed and held with no foreign matter left between the substrate 20 and the adsorption face of the stage 11. Further, in the case where the substrate 20 is a liquid crystal display panel, a flaw on the alignment film can be prevented.

### EIGHTH EMBODIMENT

FIG. 10 shows the eighth embodiment of the substrate adsorption device 1 according to the present invention. FIG. 10 is an explanatory drawing schematically illustrating a web cleaner 70.

The web cleaner 70 includes the substrate adsorption device 1 of which stage 11 is set horizontally movable in a predetermined direction, and a cleaner nozzle portion 71 fixedly held at a predetermined position. The stage 11 adsorbing and holding the substrate 20 is moved horizontally while operating the cleaner nozzle portion 71, to clean the surface of the substrate 20.

The cleaner nozzle portion 71 is set to have a comparatively short distance from the substrate 20. Therefore, if a foreign matter exists between the substrate 20 and the adsorption face of the stage 11, the cleaner nozzle portion 71 may be in contact with the substrate 20 deformed in a convex shape by the foreign matter, to damage the substrate 20.

For tackling this problem, the substrate adsorption device 1 according to the present invention is applied to the web cleaner 70. As a result, the substrate 20 can be adsorbed and held with no foreign matter existing between the substrate 20 and the adsorption face of the stage 11, so that the substrate 20 is prevented from being contact with the cleaner nozzle portion 71 and is prevented from being damaged.

### NINTH EMBODIMENT

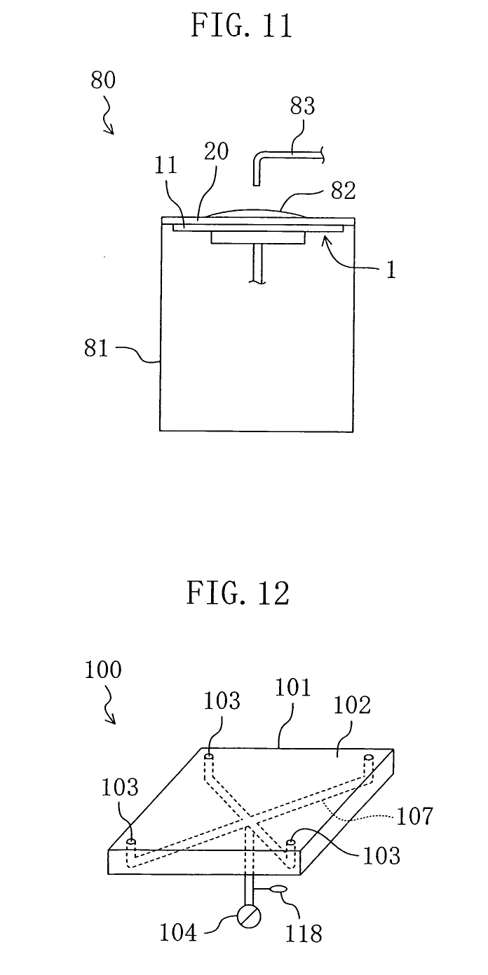

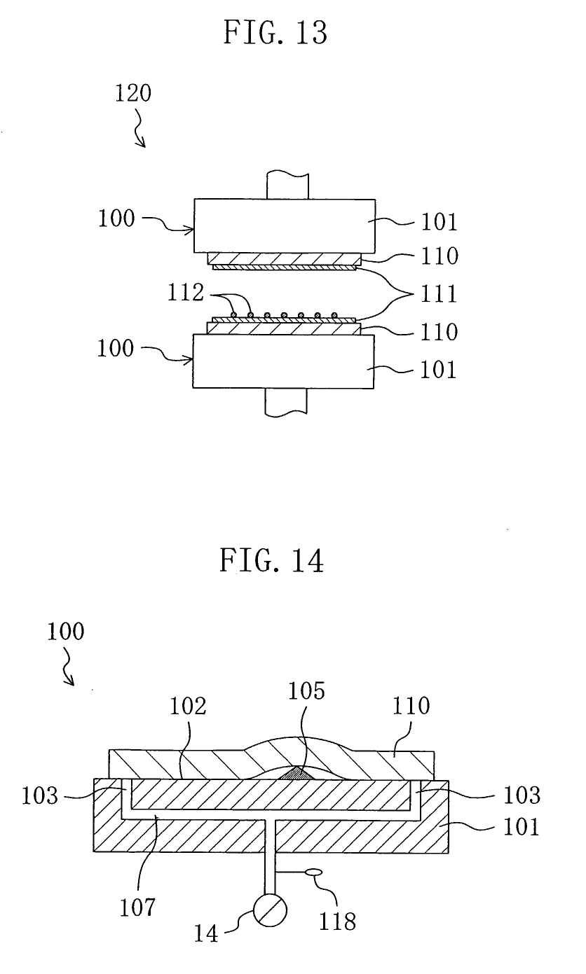

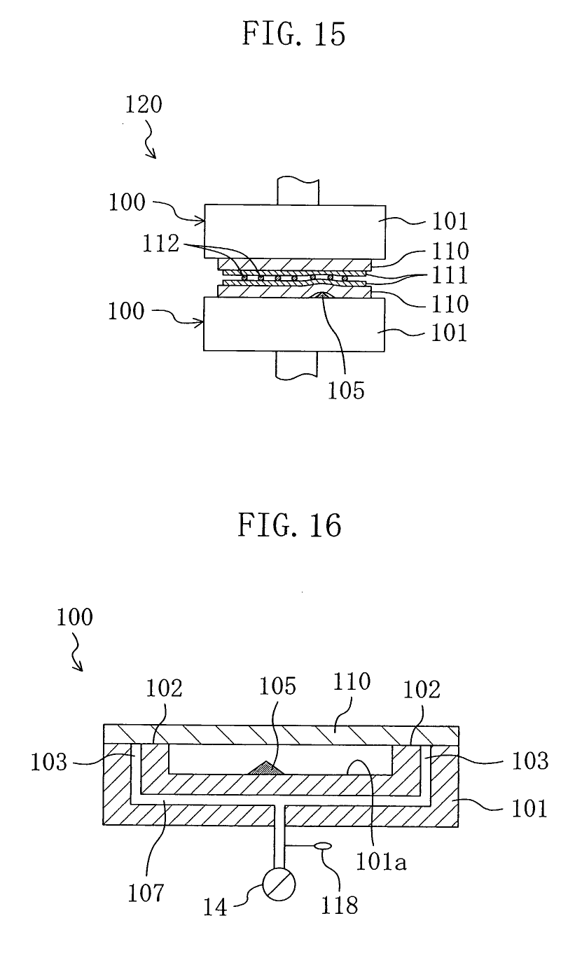

FIG. 11 shows the ninth embodiment of the substrate adsorption device 1 according to the present invention. FIG. 11 is an explanatory drawing schematically illustrating a coating apparatus 80.

The coating apparatus 80 includes a device body 81 having the substrate adsorption device 1, and a capillary nozzle 83 for supplying a coating material 82 onto the substrate 20. The substrate 20 is adsorbed and held to the stage 11 of the substrate adsorption device 1 and a predetermined amount of the coating material 82 is supplied onto the substrate 20 through the capillary nozzle 83. Thereafter, the coating material 82 is uniformly spread on the substrate 20 by a coater (not shown).

The application of the substrate adsorption device 1 according to the present invention to the coating apparatus 80 enables adsorption and holding of the substrate 20 with no foreign matter existing between the substrate 20 and the adsorption face of the stage 11, resulting in prevention of coating irregularity by the coater.

Particularly, coating irregularity in a color resist, an organic interlayer insulating film and the like of a liquid crystal display device, which are used as coated, resist lowers the display quality directly. Therefore, the application of the substrate adsorption device 1 prevents coating irregularity and enhances the display quality.

### OTHER EMBODIMENTS

The substrate adsorption device 1 according to the present invention is applicable to a polarizing plate bonding device and the like, in addition to the above embodiments. In detail, in a polarizing plate bonding device, pressure is applied to a substrate for bonding a polarizing plate to the substrate, so that the polarizing plate or the substrate itself may be scratched if a foreign matter exists between the substrate and the stage for holding the substrate. For tackling this problem, the substrate adsorbing device 1 according to the present invention is applied to the polarizing plate bonding device. Whereby, a foreign matter is prevented from being left therebetween, similar to each of the above embodiments, and accordingly, the polarizing plate and the substrate itself are prevented from being damaged.

Further, the arrangement of the leak trenches 30 is not limited to the grid pattern and the stripped pattern. Only required is that the leak trenches 30 are formed so as to be open to outside air under the condition that the substrate is adsorbed and held.

### INDUSTRIAL APPLICABILITY

As described above, the present invention is useful in substrate adsorption devices and substrate bonding devices having a stage for holding by adsorbing a substrate, and especially, is suitable to prevent damage to substrates in devices with low-cost and simple construction.

1. A substrate adsorbing device comprising:
a stage including an adsorption face for holding a substrate;
a plurality of adsorption ports formed in a region of the adsorption face of the stage;
an air discharge path connected to each of the adsorption ports;
pressure reducing means connected to the adsorption ports through the discharging path; and
pressure detecting means that detects pressure in the air discharge path,
wherein a plurality of leak trenches open to both the adsorption face of the stage and a side face of the stage are formed in a region of the stage except a region where the adsorption ports are formed.

2. The substrate adsorption device of claim 1,
wherein the pressure detecting means is provided in the air discharge path for each of the adsorption ports.

3. The substrate adsorption device of claim 1,
wherein for each of the adsorption ports, the pressure detecting means and an opening/closing mechanism for opening/closing the corresponding adsorption port based on a pressure state detected by the corresponding pressure detecting means are provided in the air discharge path.

4. The substrate adsorption device of claim 3,
wherein the opening/closing mechanism closes the corresponding adsorption port when the pressure detecting means does not detect a vacuum state.

5. The substrate adsorption device of claim 1,
wherein the leak trenches are formed in a grid pattern in the region of the adsorption face of the stage.

6. The substrate adsorption device of claim 5,
wherein the adsorption ports are formed at centers of regions surrounded by the leak trenches formed in the grid pattern, respectively.

7. The substrate adsorption device of claim 1,
wherein the leak trenches are formed in a stripped pattern in the region of the adsorption face of the stage.

8. A substrate bonding device comprising:
two substrate adsorption devices according to claim 1,
wherein the substrate adsorption devices are arranged so that the adsorption faces of the stages face each other, and
the stages are allowed to be close to each other while adsorbing and holding substrate, respectively, to bond the substrates to each other.
